(19) United States
(12) Patent Application Publication
(10) Pub. No.: US 2025/0301536 A1
(43) Pub. Date: Sep. 25, 2025

(54) TEMPERATURE CONTROL DEVICE, TEMPERATURE CONTROL METHOD, PROGRAM, PROBER, AND LEARNING MODEL GENERATING METHOD

(71) Applicant: Tokyo Seimitsu Co., Ltd., Tokyo (JP)

(72) Inventors: Tetsuo YOSHIDA, Tokyo (JP); Eiji FUKANO, Tokyo (JP); Taihei KITAGAWA, Tokyo (JP); Junsuke SATO, Tokyo (JP)

(73) Assignee: Tokyo Seimitsu Co., Ltd., Tokyo (JP)

(21) Appl. No.: 19/229,010

(22) Filed: Jun. 5, 2025

Related U.S. Application Data
(63) Continuation of application No. PCT/JP2023/041590, filed on Nov. 20, 2023.

(30) Foreign Application Priority Data
Dec. 6, 2022 (JP) 2022-195042

(51) Int. Cl. H05B 1/02; H01L 21/66; H01L 21/67; H05B 3/28

(52) U.S. Cl. CPC H05B 1/0233; H01L 21/67103; H01L 21/67248; H01L 22/12; H05B 3/28

(57) ABSTRACT

A temperature control device, a temperature control method, a program, a prober, and a learning model generating method that can implement automatic adjustment of a chuck temperature control parameter are provided. The temperature control device includes a chuck temperature acquiring unit that acquires a chuck temperature, a classifying unit which outputs a temperature change pattern in a case where the chuck temperature is input, using a learned model generated through learning with a correspondence relationship between features of changes in the chuck temperature and temperature change patterns, and a temperature control parameter setting unit that derives a temperature control parameter corresponding to the temperature change pattern output from the classifying unit and sets the temperature control parameter, and operation of a chuck temperature adjusting unit that adjusts the chuck temperature is controlled using the temperature control parameter.

### CROSS-REFERENCE TO RELATED APPLICATIONS

The present application is a Continuation of PCT International Application No. PCT/JP2023/041590 filed on Nov. 20, 2023 claiming priority under 35 U.S.C § 119 (a) to Japanese Patent Application No. 2022-195042 filed on Dec. 6, 2022. The above applications is hereby expressly incorporated by reference, in their entirety, into the present application.

### BACKGROUND OF THE INVENTION

### Field of the Invention

The present invention relates to a temperature control device, a temperature control method, a program, a prober, and a learning model generating method to be applied to inspection of electric characteristics of semiconductor chips formed on a wafer.

### Description of the Related Art

A surface of a wafer has semiconductor chips formed thereon, and the semiconductor chips include the same electric element circuits. Electric characteristics of each semiconductor chip are inspected using a wafer test system including a prober and a tester.

The prober moves a probe card having probe needles thereon and a wafer chuck relatively to each other in a state where the wafer is held on the wafer chuck, and electrically connects the probe needles to electrode pads of the semiconductor chips. The tester supplies various kinds of test signals to each semiconductor chip from a terminal electrically connected to the probe needle, receives signals output from the semiconductor chip, and analyzes the received signals to inspect whether or not the semiconductor chip normally operates.

Semiconductor chips are used in a wide range of applications under a wide temperature range. Thus, the inspection of the semiconductor chip employs temperatures corresponding to environments under which the semiconductor chips are assumed to be used, such as a room temperature, a high temperature, and a low temperature. Note that the room temperature described here may include concept referred to as an ordinary temperature. The low temperature means an environment in which the temperature is relatively low with respect to the room temperature. In a similar manner, the high temperature means an environment in which the temperature is relatively high with respect to the room temperature.

The wafer chuck of the prober includes, for example, a temperature adjusting device including a heater mechanism, a chiller mechanism, a heat pump mechanism, and the like, and heats or cools the wafer held on the wafer chuck using the temperature adjusting device.

Patent Literature 1 discloses an IC test handler which includes a temperature sensor for a wafer and which directly measures a temperature of the wafer that becomes a disturbance factor in chuck temperature control. The device disclosed in Patent Literature 1 measures a surface temperature of an IC package storing an IC using a non-contact thermometer.

Patent Literature 2 discloses an inspection device that measures a temperature of a wafer using an infrared sensor provided in a probe card. The device disclosed in Patent Literature 2 measures a temperature of an electronic device using the infrared sensor provided in the probe card when measuring the electronic device.

Patent Literature 3 discloses an inspection device that estimates an amount of heat generation of a wafer based on power output from a tester and corrects a temperature of a chuck based on the amount of heat generation of the wafer. The device disclosed in Patent Literature 3, receives power supplied from a power supply unit to an electronic device to be inspected, estimates an amount of heat generation of the electronic device based on the power supplied to the electronic device, estimates a temperature difference between the electronic device and the chuck from the amount of heat generation of the electronic device, and controls the temperature of the chuck using a value of the estimated temperature difference.

Each of the devices disclosed in Patent Literature 1 to Patent Literature 3 measures or estimates a temperature of a wafer, that is, disturbance, and performs temperature control using the measurement result or the estimation result to improve performance of temperature control in inspection of the wafer. Note that the IC disclosed in Patent Literature 1, and the electronic devices disclosed in Patent Literatures 2 and 3 correspond to the semiconductor chip formed on the wafer described above.

### CITATION LIST

### Patent Literatures

Patent Literature 1: Japanese Patent Application Laid-Open No. 2018-80919

Patent Literature 2: Japanese Patent Application Laid-Open No. 2021-128965

Patent Literature 3: Japanese Patent Application Laid-Open No. 2022-90538

### SUMMARY OF THE INVENTION

However, in the aspect disclosed in Patent Literature 1 where the temperature sensor for the wafer is provided and the aspect disclosed in Patent Literature 2 where the temperature sensor is provided in the probe card, the temperature sensor provided outside a system of the prober is required. If the wafer and the probe card cannot be equipped with the temperature sensor due to a design problem, and the like, there is a case where temperature control cannot be performed with high accuracy.

Further, in the aspect disclosed in Patent Literature 3 where the amount of heat generation of the wafer is estimated based on the power output from the tester, the power output from the tester depends on specifications of the tester, and it is difficult to perform generic measurement on a plurality of wafers whose types are different from each other.

In other words, to implement generic measurement on the plurality of wafers whose types are different from each other, it is necessary to perform temperature control using information such as a coefficient directly available by the prober, such as a temperature of a chuck.

Further, the amount of heat generation of the wafer and a heat generation pattern of the wafer differ due to a difference in type of the wafer such as a difference in type of the semiconductor chips formed on the wafer. Thus, when the temperature of a wafer is controlled with an existing temperature control parameter applied, in a case where disturbance such as a difference in type of the wafer causes a temperature change, there are concerns of occurrence of a time delay until the temperature converges to a target temperature, hunting in a control amount, and the like.

The time delay until convergence to the target temperature may cause decrease in measurement throughput. The hunting in the control amount may cause unstable temperature control, resulting in deterioration in accuracy of the temperature control. The decrease in accuracy of the temperature control leads to an inappropriate inspection of the wafer.

In a case of occurrence of the time delay until convergence to the target temperature, and the like, it is necessary to adjust the temperature control parameter for each wafer to be measured. However, heating control and cooling control are collectively performed in the temperature control of the chuck, and thus, it is not easy to determine the temperature control parameter. Further, because the wafer is a possession of a user who uses the inspection device, it is difficult to adjust the temperature control parameter using the wafer to be measured prior to the inspection. Thus, the temperature control parameter is manually adjusted in measurement of the wafer. This causes problems that adjustment of the temperature control parameter depends on persons, and productivity decreases.

The present invention has been made in view of such circumstances and aims to provide a temperature control device, a temperature control method, a program, a prober, and a learning model generating method, that may implement automatic adjustment of a chuck temperature control parameter.

A temperature control device according to a first aspect of the present disclosure includes: a chuck temperature acquiring unit configured to acquire chuck temperature indicating a temperature of a wafer chuck that holds a wafer having semiconductor chips formed thereon; a classifying unit configured to receive the chuck temperature and output a temperature change pattern corresponding to change in the received chuck temperature, using a learned model generated through learning with a correspondence relationship between features of changes in the chuck temperature and a predetermined number of temperature change patterns representing classification of the changes in the chuck temperature; and a temperature control parameter setting unit configured to derive a temperature control parameter corresponding to the temperature change pattern output from the classifying unit in a case where the classifying unit receives the chuck temperature, and set the temperature control parameter, in which operation of a chuck temperature adjusting unit configured to adjust the chuck temperature is controlled using the temperature control parameter set by the temperature control parameter setting unit.

The temperature control device according to the present disclosure, uses the classifying unit which employs learned model generated through learning with the correspondence relationship between features of changes in the chuck temperature and patterns of the changes in the chuck temperature. The temperature control parameter output from the classifying unit when the acquired chuck temperature is input to the classifying unit, is used by the temperature adjusting unit that adjusts the chuck temperature. This enables automatic adjustment of the temperature control parameter to be used by the chuck temperature adjusting unit that adjusts the chuck temperature, based on the chuck temperature.

The temperature control parameter may include a heating control parameter to be applied upon heating of the wafer chuck and a cooling control parameter to be applied upon cooling of the wafer chuck.

The temperature control parameter may include a plurality of components.

According to a second aspect, the temperature control device according to the first aspect, may include a chuck temperature change deriving unit configured to derive a change in the chuck temperature from the chuck temperatures acquired at different timings.

According to the second aspect, the temperature control parameter may be derived based on the feature of the change in the chuck temperature.

According to a third aspect, in the temperature control device according to the first aspect, the learned model learns a correspondence relationship between feature amounts representing the features of the changes in the chuck temperature and the temperature change patterns representing the classification of the changes of the chuck temperature, and the classifying unit acquires a feature amount as a feature of the change in the chuck temperature and outputs the temperature change pattern corresponding to the feature amount.

According to the third aspect, the change in the chuck temperature may be classified based on the feature amount obtained by quantifying the feature of the change in the chuck temperature.

According to a fourth aspect, in the temperature control device according to any one of the first aspect to the third aspect, the temperature control parameter setting unit may derive the temperature control parameter in which an adjustment coefficient corresponding to the temperature change pattern is used.

In the fourth aspect, a PID control parameter may be applied as the temperature control parameter.

According to a fifth aspect, the temperature control device according to any one of the first aspect to the fourth aspect, include: a wafer information acquiring unit configured to acquire wafer information including a type of a wafer to be measured; and learned models generated by performing the learning for each type of the wafer, in which the classifying unit selects one of the learned models corresponding to the type of the wafer included in the wafer information acquired by the wafer information acquiring unit.

According to the fifth aspect, the change in the chuck temperature may be classified in accordance with the type of the wafer.

A temperature control method according to a sixth aspect of the present disclosure is a temperate control method to be executed by a computer, the temperature control method including: a step of acquiring a chuck temperature indicating a temperature of a wafer chuck that holds a wafer having semiconductor chips formed thereon; a step of, in a case where the chuck temperature is input, outputting a temperature change pattern corresponding to a change in the input chuck temperature, with a classifying unit which uses a learned model generated through learning with a correspondence relationship between features of changes in the chuck temperature and a predetermined number of temperature change patterns representing classification of the changes in the chuck temperature, a step of deriving a temperature control parameter corresponding to the temperature change pattern output from the classifying unit in a case where the chuck temperature is input to the classifying unit, and setting the temperature control parameter; and a step of controlling operation of a chuck temperature adjusting unit that adjusts the chuck temperature using the temperature control parameter.

The temperature control method according to the present disclosure, enables to achieve operational effects similar to the operational effects achieved by the temperature control device according to the present disclosure.

In the temperature control method according to the present disclosure, matters similar to the subject matters specified in any one of the second aspect to the fifth aspect may be combined as appropriate. In this case, components that perform processing and functions specified in the temperature control device may be understood as components of the temperature control method that perform corresponding processing and functions.

A program according to a seventh aspect of the present disclosure is a program for causing a computer to implement: a function of acquiring a chuck temperature indicating a temperature of a wafer chuck that holds a wafer having semiconductor chips formed thereon; a function of, in a case where the chuck temperature is input, outputting a temperature change pattern corresponding to a change in the input chuck temperature, with a classifying unit which uses a learned model generated through learning with a correspondence relationship between features of changes in the chuck temperature and a predetermined number of temperature change patterns representing classification of the changes in the chuck temperature, a function of deriving a temperature control parameter corresponding to the temperature change pattern output from the classifying unit in a case where the chuck temperature is input to the classifying unit, and setting the temperature control parameter; and a function of controlling operation of a chuck temperature adjusting unit that adjusts the chuck temperature using the temperature control parameter.

The program according to the present disclosure enables to achieve operational effects similar to the operational effects achieved by the temperature control device according to the present disclosure.

In the program according to the present disclosure, matters similar to the subject matters specified in any one of the second aspect to the fifth aspect may be combined as appropriate. In this case, components that perform processing and functions specified in the temperature control device may be understood as components of the program that perform corresponding processing and functions.

A prober according to an eighth aspect of the present disclosure is a prober including: a wafer chuck configured to hold a wafer having semiconductor chips formed thereon; a probe card having probe needles; a relative moving unit configured to move the wafer chuck relatively to the probe needles; a chuck temperature adjusting device configured to adjust a temperature of the wafer chuck; and a temperature control device configured to control operation of the chuck temperature adjusting device using a temperature control parameter, in which the temperature control device includes: a chuck temperature acquiring unit configured to acquire chuck temperature indicating a temperature of a wafer chuck that holds a wafer having semiconductor chips formed thereon; a classifying unit configured to receive the chuck temperature and output a temperature change pattern corresponding to change in the received chuck temperature, using a learned model generated through learning with a correspondence relationship between features of changes in the chuck temperature and a predetermined number of temperature change patterns representing classification of the changes in the chuck temperature; and a temperature control parameter setting unit configured to derive a temperature control parameter corresponding to the temperature change pattern output from the classifying unit in a case where the classifying unit receives the chuck temperature, and set the temperature control parameter, and operation of the chuck temperature adjusting unit that adjusts the chuck temperature is controlled using the temperature control parameter set by the temperature control parameter setting unit.

The prober according to the present disclosure, enables to achieve operational effects similar to the operational effects achieved by the temperature control device according to the present disclosure.

In the prober according to the present disclosure, matters similar to the subject matters specified in any one of the second aspect to the fifth aspect may be combined as appropriate. In this case, components that perform processing and functions specified in the temperature control device may be understood as components of the probe that perform corresponding processing and functions.

A learning model generating method according to a ninth aspect of the present disclosure is a learning model generating method for generating a learned model which have learned a correspondence relationship between features of changes in a chuck temperature indicating a temperature of a wafer chuck that holds a wafer having semiconductor chips formed thereon, and a predetermined number of temperature change patterns representing classification of the changes in the chuck temperature.

The learning model generating method according to the present disclosure enables to provide a learned model to be applied to the temperature control device according to the present disclosure.

According to the present invention, the classifying unit which employs learned model generated through learning with the correspondence relationship between features of changes in the chuck temperature and patterns of the changes in the chuck temperature, is used. The temperature control parameter output from the classifying unit when the acquired chuck temperature is input to the classifying unit, is used by the temperature adjusting unit that adjusts the chuck temperature. This enables automatic adjustment of the temperature control parameter to be used by the chuck temperature adjusting unit that adjusts the chuck temperature, based on the chuck temperature.

### BRIEF DESCRIPTION OF THE DRAWINGS

FIG. 1 is a schematic configuration diagram of a prober according to an embodiment.

FIG. 2 is an external perspective view of the prober illustrated in FIG. 1.

FIG. 3 is a top view of a wafer.

FIG. 4 is a functional block diagram illustrating an electric configuration of the prober illustrated in FIG. 1.

FIG. 5 is a functional block diagram illustrating a configuration example of a chuck temperature control unit illustrated in FIG. 4.

FIG. 6 is a functional block diagram illustrating a modification of the chuck temperature control unit illustrated in FIG. 5.

FIG. 7 is a schematic diagram of optimization of a temperature control parameter during inspection of the wafer.

FIG. 8 is a schematic diagram of adjustment of a chuck temperature control parameter according to related art.

FIG. 9 is an explanatory diagram of a first pattern of a change in a chuck temperature.

FIG. 10 is an explanatory diagram of a second pattern of the change in the chuck temperature.

FIG. 11 is an explanatory diagram of a third pattern of the change in the chuck temperature.

FIG. 12 is an explanatory diagram of a fourth pattern of the change in the chuck temperature.

FIG. 13 is a schematic diagram of generation of a learned model to be applied when classifying the change in the chuck temperature into patterns.

FIG. 14 is a schematic diagram of classification of the change in the chuck temperature into the patterns, to which the learned model shown in FIG. 13 is applied.

FIG. 15 is a schematic diagram illustrating a specific example of chuck temperature control.

### DESCRIPTION OF THE EMBODIMENTS

A preferred embodiment of the present invention will be described below in accordance with the accompanying drawings. In the present specification, the same components are denoted by the same reference numerals, and redundant description will be omitted as appropriate.

### Configuration Example of prober According to Embodiment

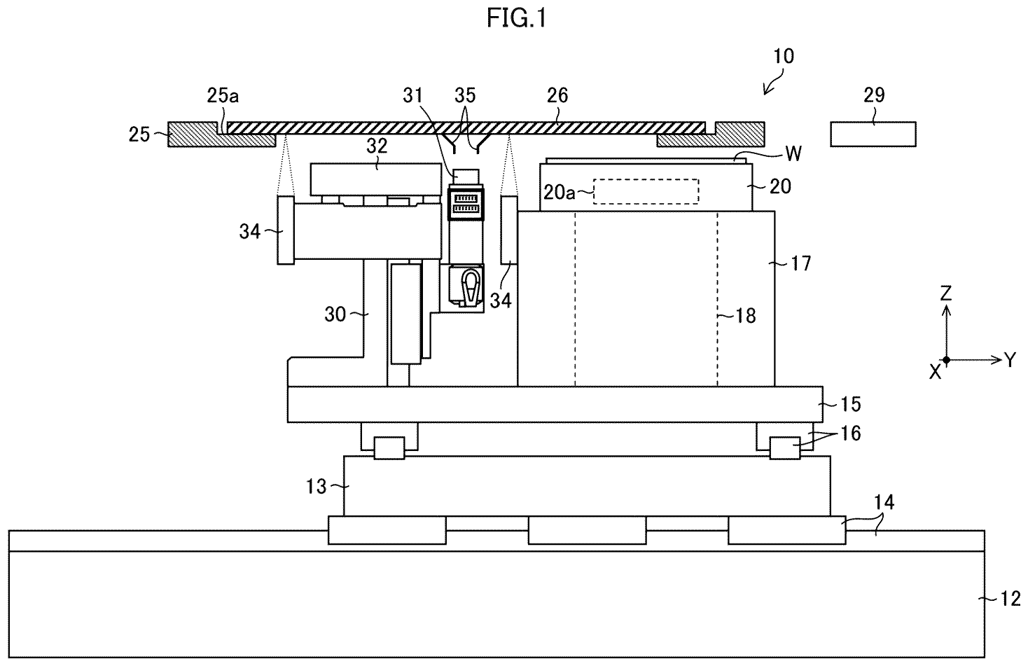

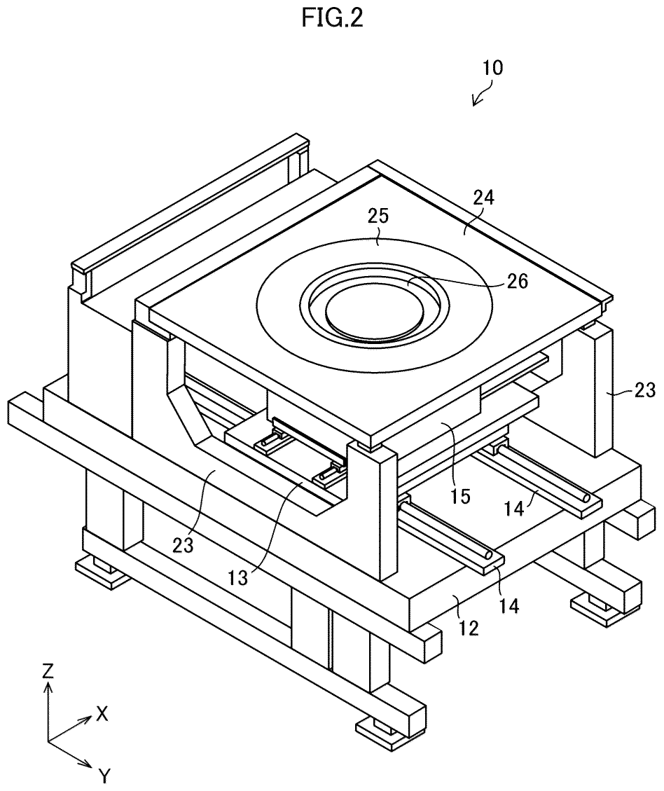

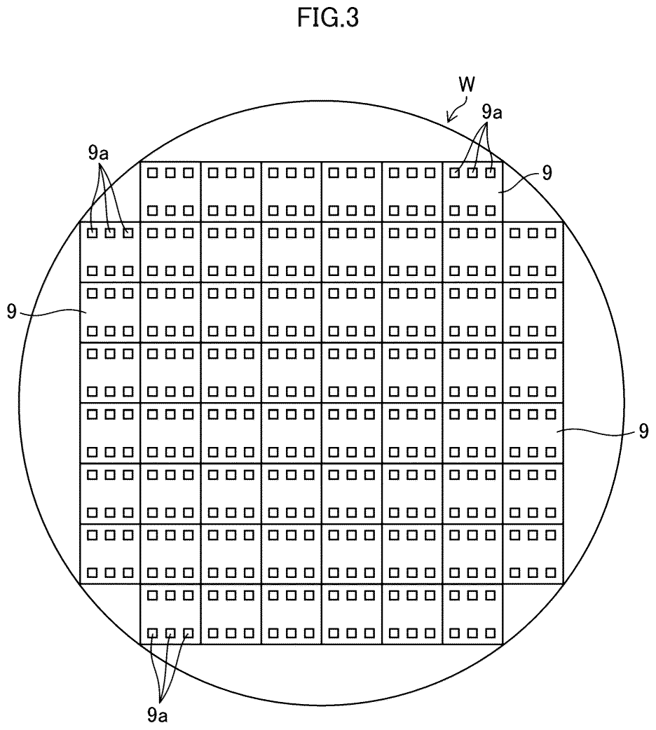

FIG. 1 is a schematic configuration diagram of a prober according to the embodiment. FIG. 2 is an external perspective view of the prober illustrated in FIG. 1. FIG. 3 is a top view of a wafer. A prober 10 illustrated in FIG. 1 and FIG. 2 is used in a wafer test system that inspects electric characteristics of semiconductor chips formed on the wafer. A wafer W to be inspected using the prober 10 is illustrated in FIG. 3.

FIG. 3 illustrates an upper surface of the wafer W supported by a wafer chuck 20. Semiconductor chips 9 are formed on the wafer W. Electrode pads 9a are formed on each semiconductor chip 9.

The prober 10 illustrated in FIG. 1 and FIG. 2 includes a base 12, a Y stage 13, a Y moving part 14, an X stage 15, an X moving part 16, a Zθ stage 17, a Zθ moving part 18, and the wafer chuck 20, which are illustrated in FIG. 1. Further, the prober 10 includes pillars 23, a head stage 24, a card holder 25, and a probe card 26, which are illustrated in FIG. 2. Still further, the prober 10 includes a wafer positioning camera 29, a vertical stage 30, a needle positioning camera 31, a cleaning plate 32, and a temperature sensor 34, which are illustrated in FIG. 1. Note that the configuration of the prober 10 is not limited to the example illustrated in FIG. 1 and FIG. 2. The configuration of the prober 10 may be modified as appropriate.

The Y stage 13 is supported on an upper surface of the base 12 so as to be able to freely move in a Y axis direction using the Y moving part 14. The Y moving part 14 moves the Y stage 13 in the Y axis direction on the upper surface of the base 12.

The Y moving part 14 includes, for example, guiderails which are disposed on the upper surface of the base 12 and are parallel to the Y axis, a slide which is disposed on a lower surface of the Y stage 13 and is engaged with the guiderails, and an actuator such as a motor that moves the Y stage 13 in the Y axis direction.

The X stage 15 is supported on an upper surface of the Y stage 13 so as to be able to freely move in an X axis direction using the X moving part 16. The X moving part 16 moves the X stage 15 in the X axis direction on the upper surface of the Y stage 13.

The X moving part 16 includes, for example, guiderails which are disposed on the upper surface of the Y stage 13 and are parallel to the X axis, a slider which is disposed on a lower surface of the X stage 15 and is engaged with the guiderails, and an actuator such as a motor that moves the X stage 15 in the X axis direction.

The Zθ stage 17 and the vertical stage 30 are disposed on an upper surface of the X stage 15. The Zθ stage 17 includes the Zθ moving part 18. The wafer chuck 20 is supported on an upper surface of the Zθ stage 17.

The Zθ moving part 18 includes, for example, a lifting mechanism that lifts the Zθ stage 17 (moves the Zθ stage 17 up and down), and a rotation mechanism that rotates the Zθ stage 17 around a rotation axis parallel to the Z axis. The Zθ moving part 18 moves the wafer chuck 20 supported on the upper surface of the Zθ stage 17 in the Z axis direction and rotates the wafer chuck 20 around the rotation axis parallel to the Z axis.

The wafer W is supported on an upper surface of the wafer chuck 20 using various kinds of support methods such as vacuum suction. Further, the wafer chuck 20 includes a chuck temperature adjusting unit 20a. The chuck temperature adjusting unit 20a adjusts a temperature of the wafer chuck 20 to adjust a temperature of the wafer W supported by the wafer chuck 20.

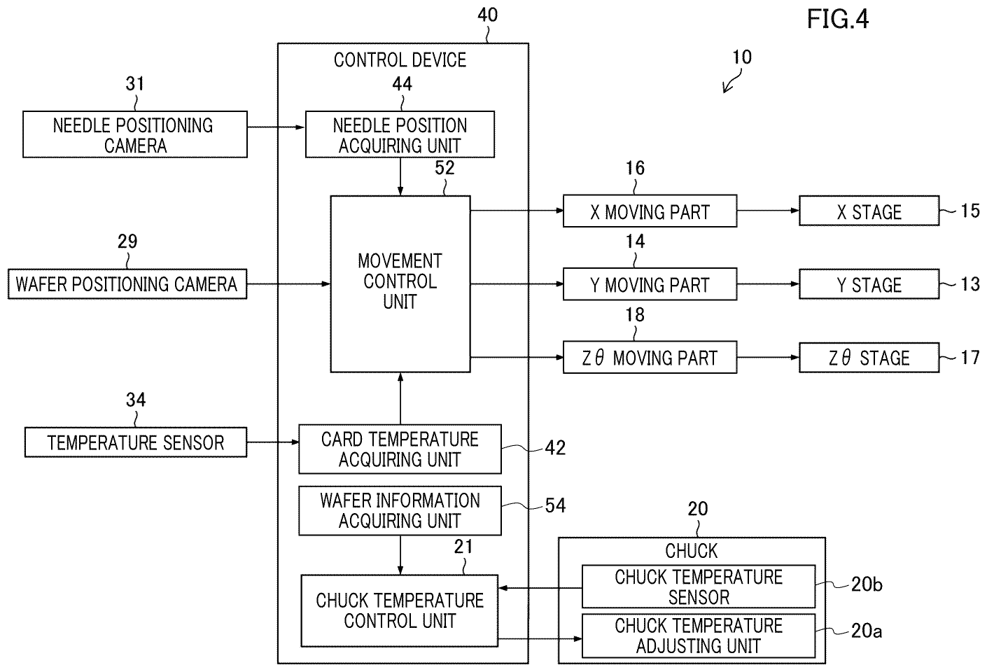

As the chuck temperature adjusting unit 20a, for example, a publicly known mechanism such as a heater mechanism, a chiller mechanism, and a heat pump mechanism is applied. Operation of the chuck temperature adjusting unit 20a is controlled based on a command signal transmitted from a chuck temperature control unit. The chuck temperature control unit is illustrated in FIG. 4 and is indicted by reference sign 21. Note that the chuck temperature adjusting unit 20a described in the embodiment is one example of a chuck temperature adjusting device that adjusts the temperature of the wafer chuck.

The wafer chuck 20 is supported so as to be able to freely move in XYZ axis directions using the Zθ stage 17, and the like, described above and is supported so as to be able to freely rotate around the rotation axis that is in a direction parallel to the Z axis. The Zθ stage 17, and the like, described above function as a relative moving unit that relatively moves the wafer W supported on the wafer chuck 20 and a probe needle 35 in an X direction, a Y direction, a Z direction and a rotation direction.

The pillars 23 illustrated in FIG. 2 are provided on the upper surface of the base 12 and support the head stage 24 at a position above the Y stage 13, the X stage 15 and the Zθ stage 17. In other words, the head stage 24 is fixed on the upper surface of the base 12 using the pillars 23.

A card holder 25 is provided at the center portion of the head stage 24. A holding hole 25a that holds an outer periphery of the probe card 26 is formed in the card holder 25. The probe card 26 is inserted into the holding hole 25a of the probe card 26 and is supported at a position facing the wafer W using the head stage 24 and the card holder 25. Note that the holding hole 25a is illustrated in FIG. 1.

The probe card 26 illustrated in FIG. 1 includes the probe needles 35 arranged in accordance with arrangement, and the like, of the electrode pads 9a on each semiconductor chip 9 to be inspected. The card holder 25 and the probe card 26 are replaced in accordance with a type of the semiconductor chip 9.

The probe card 26 includes connection terminals to be electrically connected to the probe needles 35. A tester is connected to the connection terminals. The tester supplies various kinds of test signals to the electrode pads 9a of each semiconductor chip 9 via the connection terminals of the probe card 26 and the probe needles 35, and receives signals output from the electrode pads 9a. The tester analyzes the signals output from the electrode pads 9a and tests whether or not each semiconductor chip 9 normally operates. A publicly known technique can be applied as a configuration of the tester and a test method. Here, detailed description of the configuration of the tester, and the like, will be omitted. Note that illustration of the connection terminal and the tester is omitted.

The wafer positioning camera 29 captures an image of the semiconductor chips 9 on the wafer W supported with the wafer chuck 20. The image of the semiconductor chips 9 captured using the wafer positioning camera 29 is used to detect a position of each electrode pad 9a on the semiconductor chips 9 to be inspected. The position where the wafer positioning camera 29 is disposed, a structure of the wafer positioning camera 29, and the like, are not particularly limited.

The vertical stage 30 includes the needle positioning camera 31 and the cleaning plate 32. The needle positioning camera 31 and the cleaning plate 32 are disposed at positions facing the probe card 26, and the like. Further, the vertical stage 30 includes a lifting mechanism that supports the needle positioning camera 31 and the cleaning plate 32 so as to be able to freely move in the Z axis direction. The vertical stage 30 may operate the lifting mechanism to adjust the positions of the needle positioning camera 31 and the cleaning plate 32 in the Z axis direction. Note that illustration of the lifting mechanism that may freely move in the Z axis direction is omitted.

The needle positioning camera 31 and the cleaning plate 32 are configured to be able to freely move in the Y axis direction using the Y stage 13 and the Y moving part 14 via the vertical stage 30. The needle positioning camera 31 is supported so as to be able to freely move in the X axis direction with the X stage 15 and the X moving part 16. In other words, the needle positioning camera 31, the cleaning plate 32 and the probe needles 35 are configured to be able to relatively move in the X axis direction, the Y axis direction and the Z axis direction.

The needle positioning camera 31 captures an image of the probe needle 35. The image of the probe needle 35 captured using the needle positioning camera 31 is used to detect distal end positions of probe needles 35. Specifically, an XY coordinate of the distal end position of each probe needle 35 is detected based on a position coordinate of the needle positioning camera 31, and a Z coordinate of the distal end position of each probe needle 35 is detected based on a focus position of the needle positioning camera 31.

In a case where the semiconductor chips 9 on the wafer W are inspected, the distal end positions of the probe needles 35 are detected every time the probe card 26 is replaced. The the distal end positions of the probe needles 35 may be detected every time a predetermined number of semiconductor chips 9 has been inspected.

In the detection of the distal end positions of probe needles 35, the needle positioning camera 31 is moved to a position for imaging the distal end positions of the probe needles 35, an image of the distal end positions of the probe needles 35 is captured using the needle positioning camera 31, and the distal end positions of the probe needles 35 are detected based on the captured image of the distal end positions of the probe needles 35.

Further, the positions of the electrode pads 9a on the semiconductor chips 9 on the wafer W which is to be inspected and is supported with the wafer chuck 20 are detected. Specifically, the wafer positioning camera 29 is moved to a position for imaging the electrode pads 9a on the semiconductor chips 9 on the wafer W to be inspected, an image of the electrode pads 9a is captured using the wafer positioning camera 29, and the positions of the electrode pads 9a are detected based on the captured image of the electrode pad 9a.

Then, the probe needles 35 are respectively brought into electric contact with the electrode pads 9a on the first semiconductor chip 9 to be inspected, and inspection of the first semiconductor chip 9 to be inspected is performed using the tester.

Then, the wafer W to be inspected is moved, the probe needles 35 are brought into electric contact with the electrode pads 9a on the next semiconductor chip 9 to be inspected, and inspection of the semiconductor chip 9 to be inspected is performed. This procedure is repeated, so that semiconductor chips 9 to be inspected are sequentially inspected. The distal ends of the probe needles 35 are cleaned, polished, or the like, as appropriate, using the cleaning plate 32.

Note that as a specific inspection method of the semiconductor chip 9, a publicly known inspection method such as an inspection method disclosed in, for example, Japanese Patent Application Laid-Open No. 2018-117095 may be applied. Here, detailed description of the inspection method of the semiconductor chip 9 will be omitted.

The temperature sensor 34 is provided at a position facing a lower surface of the card holder 25 and a lower surface of the probe card 26. The lower surface of the card holder 25 is opposite to a surface of the card holder 25, on which the probe card 26 is supported. The lower surface of the probe card 26 is a surface which is supported by the card holder 25.

As arrangement examples of the temperature sensor 34, the temperature sensor 34 may be disposed on a side surface of the Zθ stage 17, or on a side surface of the vertical stage 30, or the like. The temperature sensor 34 is supported so as to be able to freely relatively move with respect to the card holder 25 and the probe card 26 with the Y stage 13, the X stage 15, the Zθ stage 17, and the vertical stage 30.

As the temperature sensor 34, for example, a non-contact type temperature sensor using a radiation energy detection scheme may be applied. The temperature sensor 34 may perform measurement of the temperatures of the card holder 25 and the probe card 26 in a non-contact manner. The card holder 25 and the probe card 26 may be affected by the temperature of the wafer chuck 20, so as to thermally deform. The distal end positions of the probe needles 35 may be displaced with respect to specified positions due to thermal deformation of the card holder 25, and the like.

The prober 10 may measure the temperatures of the card holder 25 and the probe card 26 using the temperature sensor 34 and predict a displacement of the distal end position of each probe needle 35 due to thermal deformation of the card holder 25, and the like. For example, the prober 10 may predict a displacement amount and a displacement direction of the distal end position of a probe needle 35 as the displacement of the distal end position of the probe needle 35.

### Electric Configuration Example of Prober According to Embodiment

FIG. 4 is a functional block diagram illustrating an electric configuration of the prober illustrated in FIG. 1. FIG. 4 mainly illustrates a function regarding temperature control of the wafer chuck 20 and a function regarding contact control between the probe needles 35 and the electrode pads 9a on the semiconductor chip 9 on the wafer W, and illustration of other functions is omitted as appropriate.

The control device 40 performs integrated control on respective parts of the prober 10. As the control device 40, a computer is applied. The control device 40 executes various kinds of programs corresponding to functions of the respective parts of the prober 10 to implement the functions of the respective parts of the prober 10. The control device 40 may be disposed in the body of the prober 10 or may be disposed outside the prober 10.

The computer may take a form of a server, a personal computer, a work station, a tablet terminal, or the like. The computer may take a form of virtual machine.

The various kinds of programs may be stored in a storage device provided in the control device 40 or may be stored in a storage device located outside the control device 40 and provided inside the prober 10. The control device 40 may acquire the various kinds of programs from the storage device outside the prober 10.

The control device 40 includes an arithmetic circuit including various kinds of processors, memories, and the like. Examples of the various kinds of processors can include a central processing unit (CPU), a graphics processing unit (GPU), an application specific integrated circuit (ASIC), a programmable logic device, and the like.

Examples of the programmable logic device may include a simple programmable logic devices (SPLD), a complex programmable logic device (CPLD), a field programmable gate arrays (FPGA), and the like. Various kinds of functions of the control device 40 may be implemented using one processor or may be implemented using processors. Processors may be processors of the same type or processors of types different from each other.

The control device 40 includes various kinds of communication interfaces. The control device 40 is connected to peripheral equipment such as the wafer positioning camera 29, the needle positioning camera 31 and the temperature sensor 34 via various kinds of communication interfaces so as to be able to freely perform communication. Various kinds of standards such as universal serial bus (USB) may be applied as the communication interfaces. The communication interfaces may take either a wired communication form or a wireless communication form.

The control device 40 includes the chuck temperature control unit 21. The chuck temperature control unit 21 controls operation of the chuck temperature adjusting unit 20a provided to the wafer chuck 20. The chuck temperature control unit 21 acquires the chuck temperature from the chuck temperature sensor 20b provided to the wafer chuck 20. Details of the chuck temperature control unit 21 will be described later.

The control device 40 includes a card temperature acquiring unit 42. The card temperature acquiring unit 42 acquires the temperature of the card holder 25 and the temperature of the probe card 26 output from the temperature sensor 34. The card temperature acquiring unit 42 includes a communication interface that supports the output signal output from the temperature sensor 34.

The control device 40 includes a needle position acquiring unit 44. The needle position acquiring unit 44 acquires the captured image of the distal end positions of the probe needles 35 output from the needle positioning camera 31. The needle position acquiring unit 44 acquires information of the distal end positions of the probe needles 35 from the captured image of the distal end positions of the probe needles 35. The acquisition of the information may include concept of processing original information to generate desired information.

The control device 40 includes a movement control unit 52. The movement control unit 52 controls operation of the X moving part 16 to drive the X stage 15. The movement control unit 52 controls operation of the Y moving part 14 to drive the Y stage 13. The movement control unit 52 controls operation of the Zθ moving part 18 to drive the Zθ stage 17.

The movement control unit 52 acquires the positions of the semiconductor chips 9 to be inspected from the captured image of the semiconductor chip 9 to be inspected transmitted from the wafer positioning camera 29. Further, the movement control unit 52 acquires information of the distal end positions of the probe needles 35 from the needle position acquiring unit 44.

In a case where the wafer W is inspected, the movement control unit 52 drives the X stage 15, the Y stage 13, and the Zθ stage 17 to move the wafer W relatively to the probe needle 35 and sequentially brings semiconductor chips 9 to be inspected into contact with the probe needles 35.

The movement control unit 52 may acquire the temperature of the card holder 25 and the temperature of the probe card 26 using the card temperature acquiring unit 42, to correct variation of the distal end position of the probe needle 35 due to a temperature change in the temperature of the card holder 25, and the like.

The control device 40 includes a wafer information acquiring unit 54. The wafer information acquiring unit 54 acquires wafer information that specifies a type of the wafer W to be inspected. The wafer information includes information of a type of the semiconductor chips 9 formed on the wafer W. The chuck temperature control unit 21 controls the chuck temperature based on the wafer information acquired using the wafer information acquiring unit 54. The wafer information acquiring unit 54 may be configured as a component of the chuck temperature control unit 21.

### Configuration Example of Chuck Temperature Control Unit

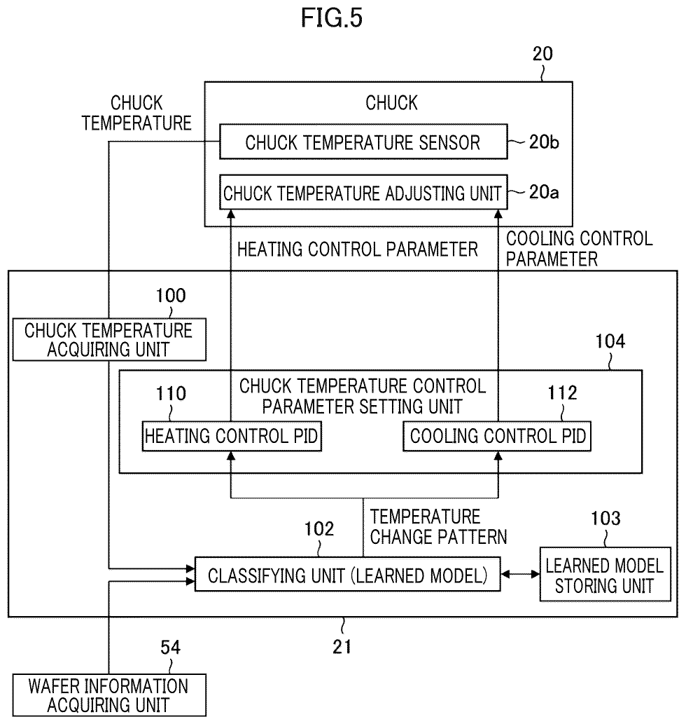

FIG. 5 is a functional block diagram illustrating a configuration example of the chuck temperature control unit illustrated in FIG. 4. The chuck temperature control unit 21 may be configured as a temperature control device to which a computer is applied. A computer similar to the computer that functions as the control device 40 illustrated in FIG. 4 may be used as the computer that functions as the temperature control device.

The chuck temperature control unit 21 illustrated in FIG. 5 uses the chuck temperature, and automatically adjusts a chuck temperature control parameter to be applied to the chuck temperature adjusting unit 20a. The chuck temperature control unit 21 includes a learned model (trained model).

The chuck temperature control unit 21 includes a chuck temperature acquiring unit 100, a classifying unit 102, a learned model storing unit 103, and a chuck temperature control parameter setting unit 104. The chuck temperature acquiring unit 100 acquires the chuck temperature according to a sampling period specified in advance.

The classifying unit 102 classifies a change in the chuck temperature into one of temperature change patterns specified in advance based on the chuck temperature acquired using the chuck temperature acquiring unit 100. The classifying unit 102 employs a learned model obtained by performing supervised learning using a relationship between features of changes in the chuck temperature and temperature change patterns, as learning data.

The learned model storing unit 103 stores one or more learned models to be applied to the classifying unit 102. The classifying unit 102 reads the learned model from the learned model storing unit 103 and classifies the change in the chuck temperature.

The learned model storing unit 103 may store learned models respectively corresponding to types of the wafer W. The classifying unit 102 may select one learned model corresponding to the wafer information to be inspected acquired using the wafer information acquiring unit 54, and classify the change in the chuck temperature.

The learned models to be stored in the learned model storing unit 103 may be generated using a computer. The computer applied to generation of the learned models may be a device outside the chuck temperature control unit 21 or may be a device provided in the chuck temperature control unit 21.

The chuck temperature control parameter setting unit 104 acquires the temperature change pattern output from the classifying unit 102 in response to input of the chuck temperature, and derives a chuck temperature control parameter corresponding to the temperature change pattern.

The chuck temperature control parameter setting unit 104 includes a heating control parameter deriving unit 110 that derives a heating control parameter, and a cooling control parameter deriving unit 112 that derives a cooling control parameter.

The chuck temperature control parameter setting unit 104 includes a heating control parameter and the cooling control parameter for the chuck temperature adjusting unit 20a as the chuck temperature control parameter.

In the present embodiment, a PID control parameter is indicated as an example of the chuck temperature control parameter. Heating control PID illustrated in FIG. 5 corresponds to the heating control parameter deriving unit 110, which means that the PID control parameter is derived as the heating control parameter to be applied to heating control. Further, cooling control PID illustrated in FIG. 5 corresponds to the cooling control parameter deriving unit 112, which means that the PID control parameter is derived as the cooling control parameter to be applied to cooling control. Note that P of PID is an initial character of Proportional representing proportion, I is an initial character of Integral representing integration, and D is an initial character of Derivative representing differentiation.

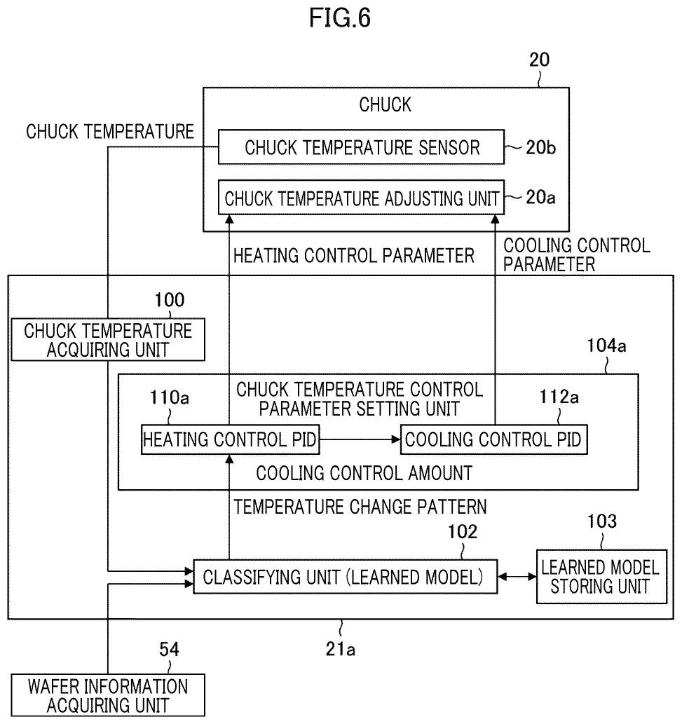

FIG. 6 is a functional block diagram illustrating a modification of the chuck temperature control unit illustrated in FIG. 5. The chuck temperature control unit 21a illustrated in FIG. 6 includes a chuck temperature control parameter setting unit 104a instead of the chuck temperature control parameter setting unit 104 illustrated in FIG. 5.

The chuck temperature control parameter setting unit 104a includes a heating control parameter deriving unit 110a and a cooling control parameter deriving unit 112a. The heating control parameter deriving unit 110a acquires the temperature change pattern output from the classifying unit 102 and derives a heating control parameter corresponding to the temperature change pattern. Further, the heating control parameter deriving unit 110a derives a cooling control amount based on the heating control parameter.

The cooling control parameter deriving unit 112a acquires a cooling control amount from the heating control parameter deriving unit 110a and derives a cooling control parameter based on the cooling control amount. The chuck temperature control parameter setting unit 104a sets the heating control parameter and the cooling control parameter for the chuck temperature adjusting unit 20a as the chuck temperature control parameter.

### Specific Example of Chuck Temperature Control During Wafer Inspection

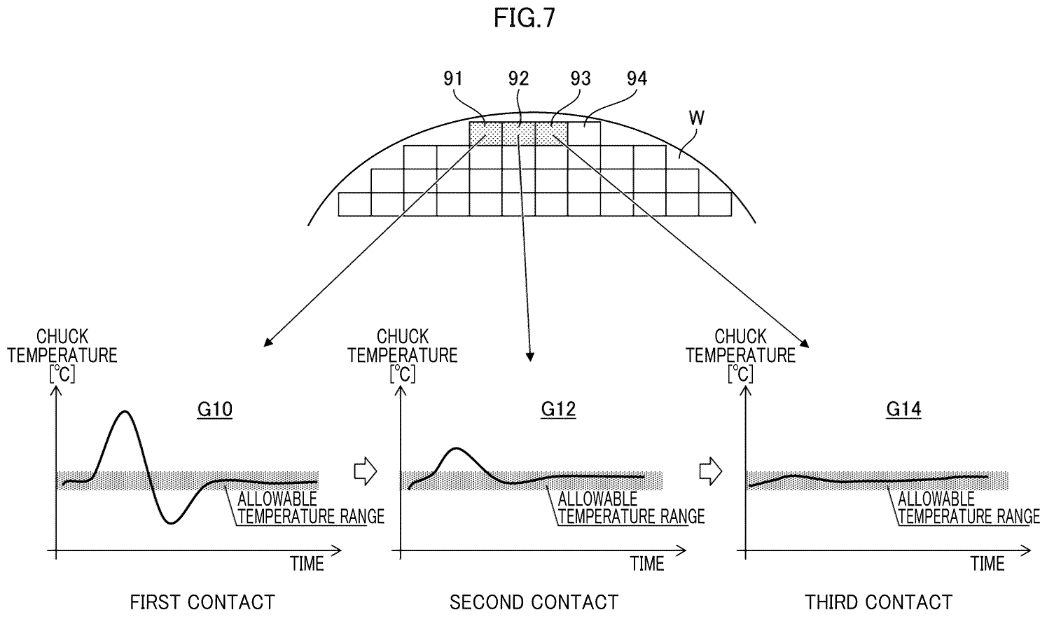

FIG. 7 is a schematic diagram of optimization of the temperature control parameter during wafer inspection. FIG. 7 indicates a change in the chuck temperature using graphs. In each graph, a horizontal axis indicates time and a vertical axis indicates the chuck temperature. The chuck temperature is acquired multiple times during an inspection period of one semiconductor chip 9, and a change in the chuck temperature as shown in the graphs G10 and the like, is acquired. A temperature range parallel to a time axis shown in the graphs G10 and the like, indicates an allowable temperature range of the chuck temperature during inspection of the wafer W.

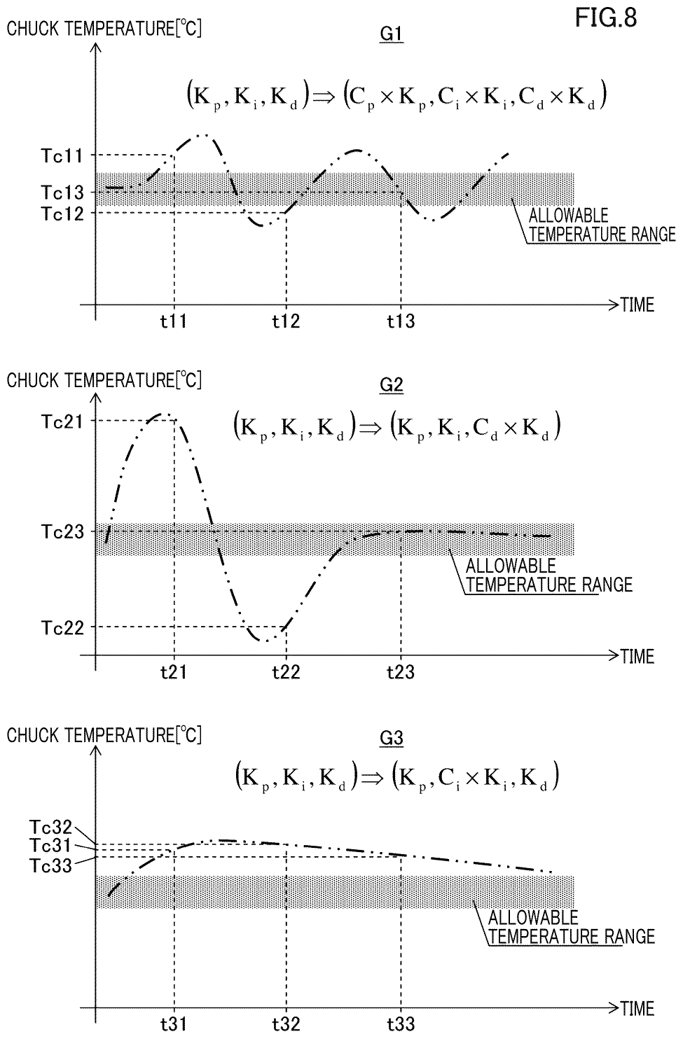

A first contact shown in FIG. 7 represents inspection of a semiconductor chip 91. In the inspection of the semiconductor chip 91, a specified initial value in the chuck temperature control parameter is applied, to perform temperature control of the wafer chuck 20. Note that a curve in each of the graphs G10 and the like shown in FIG. 8 is a virtual curve representing temperature history.

The graph G10 represents a change in the chuck temperature acquired during the inspection of the semiconductor chip 91. A period during the inspection of the semiconductor chip 91 is a period from a timing at which the probe needle 35 is brought into contact with the semiconductor chip 91 until when the tester completes measurement and contact between the probe needle 35 and the semiconductor chip 91 is released.

The measurement of the chuck temperature during the inspection of the semiconductor chip 91 is performed as background processing of the inspection of the semiconductor chip 91. Measurement of the chuck temperature does not have to be performed in response to contact between the probe needle 35 and the semiconductor chip 9. A fixed sampling period may be continuously applied to the inspection of the semiconductor chips 9 to perform sampling of the chuck temperature.

There is a case where the chuck temperature during the inspection of the semiconductor chip 91 may deviate from the allowable temperature range. In this case, the chuck temperature control parameter is adjusted. The chuck temperature control parameter setting unit 104 illustrated in FIG. 5 derives the chuck temperature control parameter corresponding to the change in the chuck temperature shown in the graph G10 in FIG. 7 and sets the derived chuck temperature control parameter for the chuck temperature adjusting unit 20a.

In inspection of a semiconductor chip 92 shown as a second contact, a new chuck temperature control parameter is set, and temperature control of the wafer chuck 20 is performed. A graph G12 represents a change in the chuck temperature acquired during the inspection of the semiconductor chip 92.

The chuck temperature during the inspection of the semiconductor chip 92 is improved compared to the chuck temperature during the inspection of the semiconductor chip 91, but the chuck temperature occasionally deviates from the allowable temperature range during the inspection of the semiconductor chip 92. The chuck temperature control parameter setting unit 104 derives a chuck temperature control parameter corresponding to the change in the chuck temperature shown in the graph G12 in FIG. 7 and sets the acquired chuck temperature control parameter for the chuck temperature adjusting unit 20a.

In inspection of a semiconductor chip 93 shown as a third contact, a new chuck temperature control parameter is set, and temperature control of the wafer chuck 20 is performed. A graph G14 represents a change in the chuck temperature acquired during the inspection of the semiconductor chip 93.

The chuck temperature during the inspection of the semiconductor chip 93 is improved compared to the chuck temperature during the inspection of the semiconductor chip 92 and falls within the allowable temperature range. In this manner, the chuck temperature control parameter is updated for each contact, so that the chuck temperature control parameter is optimized. By this means, the temperature control of the wafer chuck 20 is performed with the chuck temperature control parameter optimally selected for the wafer to be inspected.

FIG. 8 is a schematic diagram of adjustment of the chuck temperature control parameter according to the related art. FIG. 8 illustrates a change in the chuck temperature with graphs. Note that, in a graph G1, a graph G2 and a graph G3 shown in FIG. 8, a horizontal axis indicates time and a vertical axis indicates the chuck temperature.

In the temperature control of the wafer chuck 20 according to the related art, an operator grasps the change in the chuck temperature and adjusts a PID control parameter (Kₚ, Kᵢ, K_{d}) to be applied as a chuck temperature control parameter based on an experimental viewpoint of the operator.

For example, in a case where chuck temperatures Tc11, Tc12, and Tc13 are acquired respectively at a sampling timing t11, a sampling timing t12, and a sampling timing t13 as shown in the graph G1, an adjustment coefficient Cₚ, an adjustment coefficient Cᵢ, and an adjustment coefficient C_{d} are derived based on the experimental viewpoint of the operator, respectively for a p parameter Kₚ, an i parameter Kᵢ, and a d parameter K_{d} of the PID control parameter (Kₚ, Kᵢ, K_{d}) that has been set in advance as the chuck temperature control parameter. Then, a new PID control parameter (Cₚ×Kₚ, Cᵢ×Kᵢ, C_{d}×K_{d}) is set by multiplying the PID control parameter (Kₚ, Kᵢ, K_{d}) by the adjustment coefficient (Cₚ, Cᵢ, C_{d}).

Further, in a case where chuck temperatures Tc21, Tc22, and Tc23 are acquired respectively at a sampling timing t21, a sampling timing t22, and a sampling timing t23 as shown in the graph G2, an adjustment coefficient C_{d} is derived for the d parameter K_{d}, based on the experimental viewpoint of the operator. Still further, in a case where chuck temperature Tc31, Tc32, and Tc33 are acquired respectively at a sampling timing t31, a sampling timing t32, and a sampling timing t33 as shown in the graph G3, an adjustment coefficient Cᵢ is derived for an i parameter Kᵢ, based on the experimental viewpoint of the operator. In other words, in the chuck temperature control according to the related art, the chuck temperature control parameter is set based on the experimental viewpoint of the operator using one or more chuck temperatures acquired during the inspection of the wafer W.

### Explanation of Learning Model to be Applied to Classifying Unit

The chuck temperature control unit 21 according to the present embodiment performs automatic adjustment of the chuck temperature control parameter by applying machine learning. The machine learning to be applied to the chuck temperature control unit 21 will be described in detail below.

While FIG. 8 illustrates three types of the change in the chuck temperature, there are an infinite number of types of the change in the chuck temperature. It is difficult to perform machine learning targeted at all of the infinite types of the change in the chuck temperature. Thus, a learned model that classifies the change in the chuck temperature into patterns is generated and applied to the classifying unit 102 shown in FIG. 5.

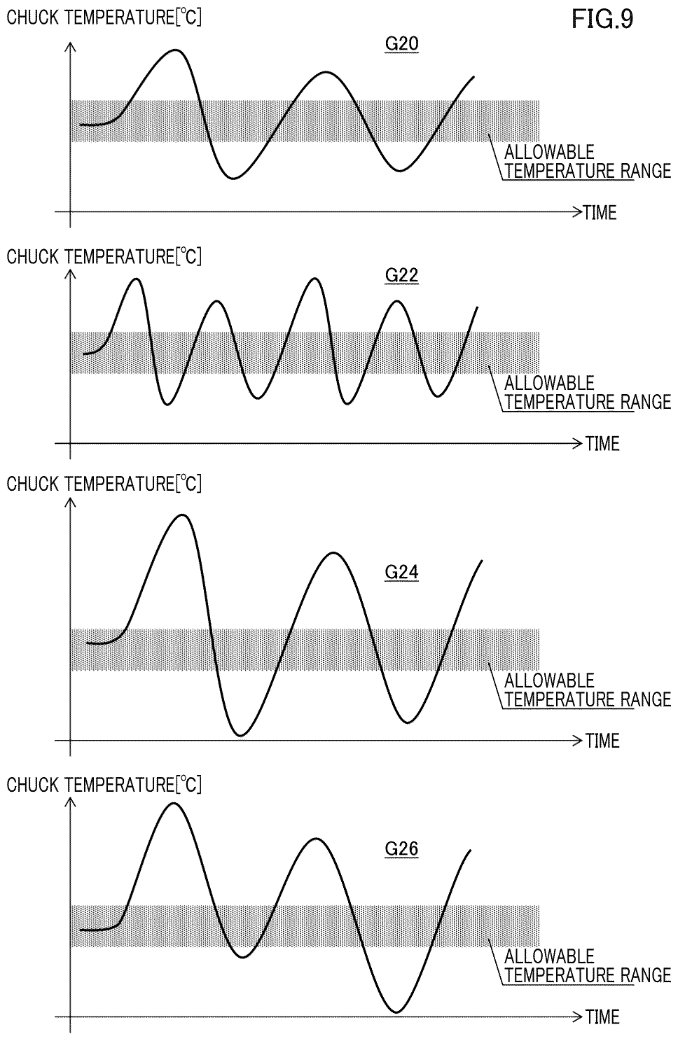

FIG. 9 is an explanatory diagram of a first pattern of the change in the chuck temperature. FIG. 9 shows the change in the chuck temperature with graphs. In each graph, a horizontal axis indicates time and a vertical axis indicates the chuck temperature. Each of a graph G20, a graph G22, a graph G24, and a graph G26 shown in FIG. 9 represents the first pattern in which hunting of the chuck temperature occurs.

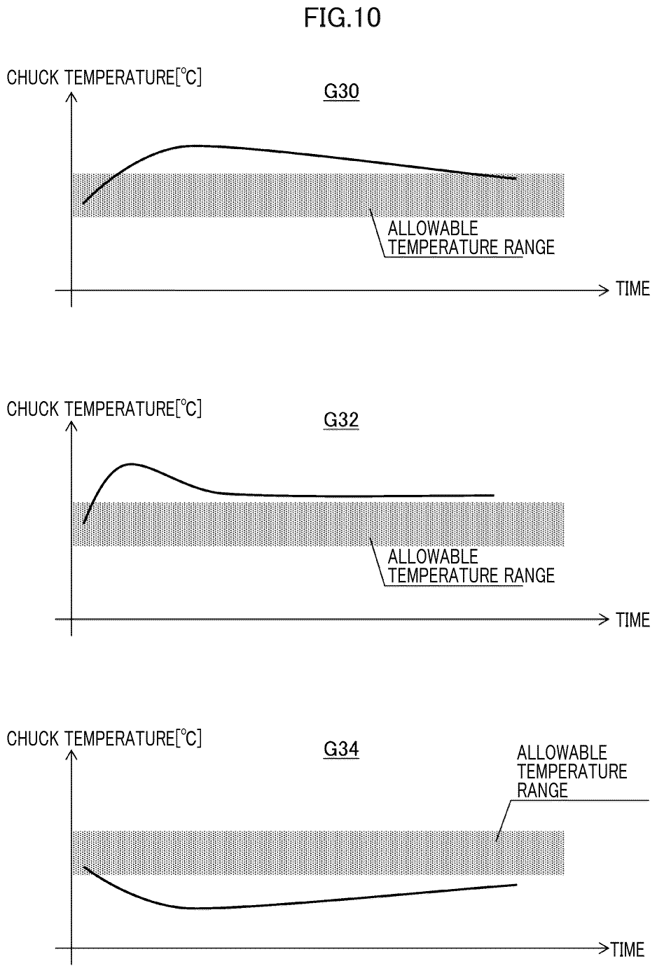

FIG. 10 is an explanatory diagram of a second pattern of the change in the chuck temperature. FIG. 10 shows the change in the chuck temperature with graphs similar to FIG. 9. Each of a graph G30, a graph G32, and a graph G34 shown in FIG. 10 represents the second pattern in which a convergence period of the change in the chuck temperature is long.

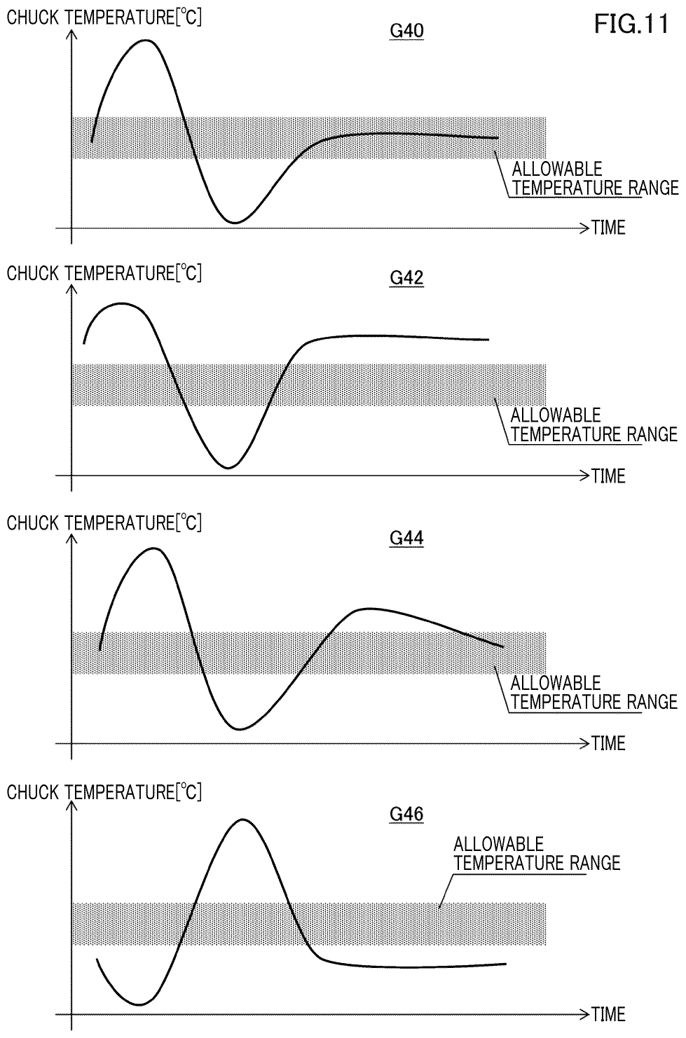

FIG. 11 is an explanatory diagram of a third pattern of the change in the chuck temperature. FIG. 11 shows the change in the chuck temperature with graphs similar to FIG. 9 and FIG. 10. Each of a graph G40, a graph G42, a graph G44, and a graph G46 shown in FIG. 11 represents the third pattern in which the change amount (variation) in the chuck temperature is large.

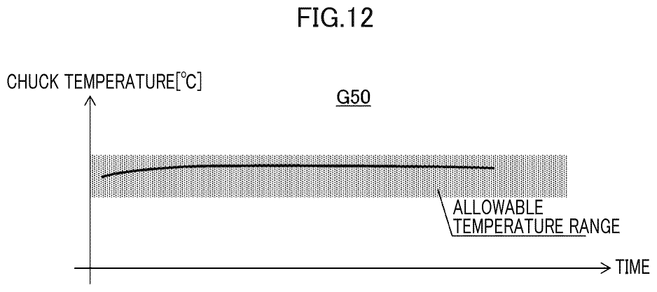

FIG. 12 is an explanatory diagram of a fourth pattern of the change in the chuck temperature. FIG. 12 shows the change in the chuck temperature with a graph similar to FIG. 9 to FIG. 11. A graph G50 shown in FIG. 12 represents the fourth pattern in which the chuck temperature is stable.

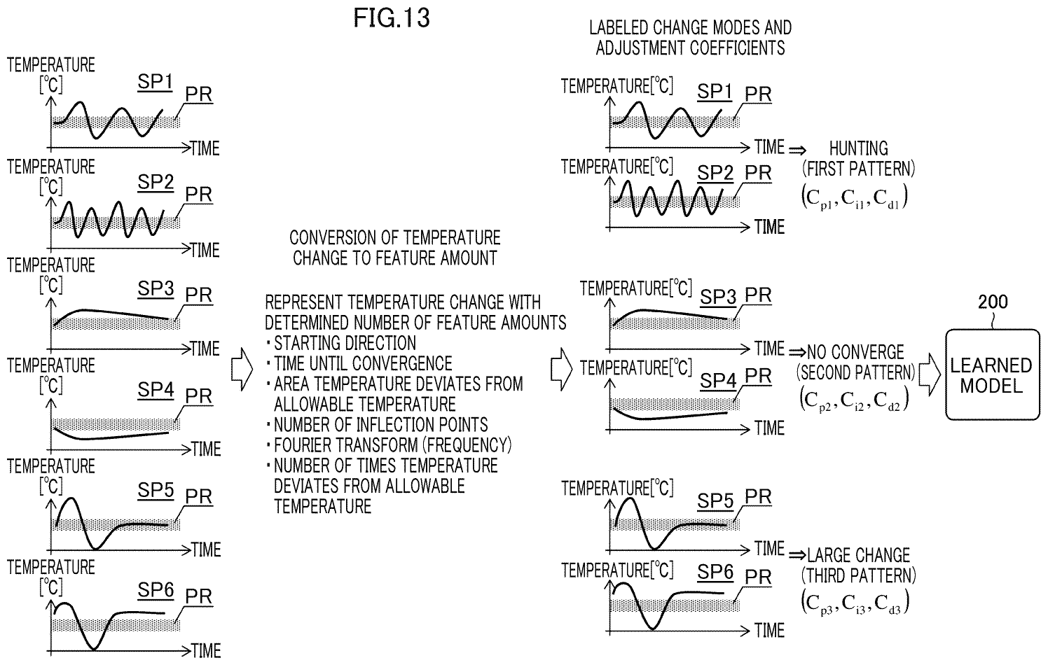

FIG. 13 is a schematic diagram of generation of the learned model to be applied when classifying the change in the chuck temperature into patterns. First, temperature change samples showing the changes in the chuck temperature, are represented using a determined number of feature amounts, and labels are assigned to the patterns of the temperature change in the chuck temperature. FIG. 13 shows a temperature change sample SP1, a temperature change sample SP2, a temperature change sample SP3, a temperature change sample SP4, a temperature change sample SP5, and a temperature change sample SP6 as the plurality of temperature change samples.

The change in the chuck temperature may be converted to a feature amount from the several perspectives. Examples of such perspectives include a starting direction of the temperature change, a period until the temperature change converges, an area of a temperature deviating from the allowable temperature range, the number of inflection points of the temperature change, a frequency of the temperature change and the number of times the temperature deviates from the allowable temperature range, and the like.

The starting direction of the temperature change is calculated from a temperature measurement value in first sampling and a temperature measurement value in second sampling. In the starting direction of the temperature change, a direction in which the temperature rises may be set as a positive direction, and a direction in which the temperature decreases may be set as a negative direction.

The area of the temperature deviating from the allowable temperature range is an area of parts that deviate from the allowable temperature range PR in a curve representing the temperature change. The number of inflection points of the temperature change is the number of inflection points in the curve representing the temperature change. The frequency of the temperature change is a frequency in the curve representing the temperature change and is obtained by performing Fourie transform on the curve representing the temperature change.

As shown in FIG. 13, a label of the first pattern in which hunting of the change in the chuck temperature occurs is assigned to the temperature change sample SP1 and the temperature change sample SP2. In a similar manner, a label of the second pattern in which the convergence period of the change in the chuck temperature is long is assigned to the temperature change sample SP3 and the temperature change sample SP4, and a label of the third pattern in which the change in the chuck temperature is large is assigned to the temperature change sample SP5 and the temperature change sample SP6.

A learned model 200 is generated by performing learning (training) using pairs as learning data. Each pair includes: the feature amount representing the temperature change; and the temperature change pattern into which the change in the chuck temperature is classified. In a case where the feature amount of the change in the chuck temperature is input, the learned model 200 outputs the temperature change pattern corresponding to the feature amount of the change in the chuck temperature.

Examples of an algorithm of supervised machine learning to be applied to the learned model 200 may include a k-nearest neighbor algorithm, a decision tree such as a classification tree, random forest, non-linear SVM, a neural network, and the like. Note that the SVM is an abbreviation of Support-Vector Machine.

The learned model 200 is generated as a result of learning being performed for each type of the wafer W. Indexes indicating the types of the wafer W, are assigned to learned models 200 respectively corresponding to types of the wafer W.

The chuck temperature control unit 21 illustrated in FIG. 5 may include a feature amount deriving unit that derives (calculates) a feature amount corresponding to the change in the chuck temperature from the change in the chuck temperature. In other words, the classifying unit 102 may include the feature amount deriving unit, so as to output the temperature change pattern corresponding to the change in the chuck temperature in a case where the change in the chuck temperature is input. The feature amount deriving unit may be a component of the classifying unit 102.

Further, the chuck temperature control unit 21 may include a chuck temperature change deriving unit that derives (calculates) the change in the chuck temperature from chuck temperatures sequentially acquired in chronological order. In other words, the classifying unit 102 may include the chuck temperature change deriving unit so as to output the temperature change pattern corresponding to the change in the chuck temperature in a case where chuck temperatures sequentially acquired in chronological order are input.

In other words, the classifying unit 102 may include a chuck temperature change deriving unit that drives (calculates) the change in the chuck temperature corresponding to a format of input data representing the input chuck temperature. The learned model 200 may be understood as a learned model obtained by learning a relationship between a feature of the change in the chuck temperature and a pattern of the change in the chuck temperature. Note that the learned model 200 described in the present embodiment is one example of the learned model obtained by learning a correspondence relationship between the feature of the change in the chuck temperature and the temperature change pattern into which the change in the chuck temperature is classified.

An adjustment coefficient to be applied to the chuck temperature control parameter is associated with each of patterns of the changes in the chuck temperature. In the example shown in FIG. 13, an adjustment coefficient (Cₚ₁, Cᵢ₁, C_{d1}) to be applied to the chuck temperature control parameter (Kₚ, Kᵢ, K_{d1}) is associated with the first pattern in which hunting of the change in the chuck temperature occurs. In a similar manner an adjustment coefficient (Cₚ₂, Cᵢ₂, C_{d2}) is associated with the second pattern in which the convergence period of the change in the chuck temperature is long, and an adjustment coefficient (Cₚ₃, Cᵢ₃, C_{d3}) is associated with the third pattern in which the change in the chuck temperature is large.

Regarding a relationship between the pattern of the change in the chuck temperature and the adjustment coefficient, firstly, the chuck temperature control parameter (Kₚ, Kᵢ, K_{d}) is repeatedly adjusted for each pattern of the change in the chuck temperature, and then the relationship between the pattern of the change in the chuck temperature and the adjustment coefficient is derived from a relationship between the chuck temperature control parameter with which the chuck temperature finally becomes stable and the initial value of the chuck temperature control parameter. Note that procedure of generating the learned model 200 described in the embodiment is one example of the learning model generating method.

### Operation of Learned Model

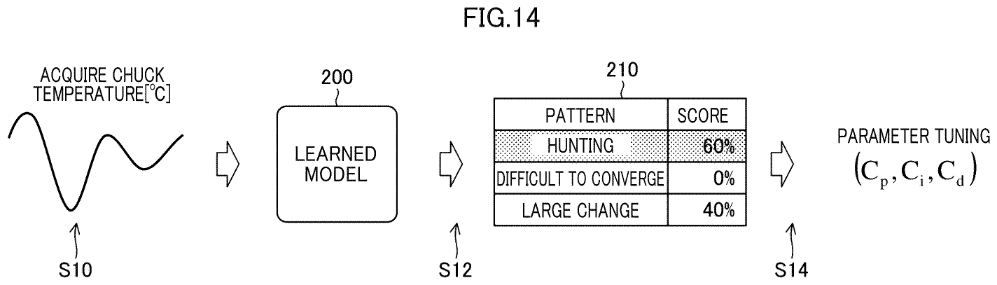

FIG. 14 is a schematic diagram of classification of the change in the chuck temperature into patterns, to which the learned model shown in FIG. 13 is applied. FIG. 14 shows procedure of a chuck temperature control method of classifying the chuck temperature into one of temperature change patterns specified in advance, and deriving the adjustment coefficient corresponding to the temperature change pattern.

In a chuck temperature acquiring step S10, the chuck temperature is acquired using the chuck temperature acquiring unit 100 illustrated in FIG. 5. In a classifying step S12, the classifying unit 102 illustrated in FIG. 5 outputs the temperature change pattern corresponding to the change in the chuck temperature. FIG. 14 shows an example where a score representing a likelihood (probability) for each temperature change pattern, as an output 210 of the temperature change pattern.

In a chuck temperature control parameter acquiring step S14, the chuck temperature control parameter setting unit 104 outputs the chuck temperature control parameter corresponding to the temperature change pattern output from the classifying unit 102 in the classifying step S12. FIG. 14 shows an example where the first pattern in which hunting of the change in the chuck temperature occurs, has the highest score, and the first pattern is employed as the temperature change pattern, and the adjustment coefficient (Cₚ, Cᵢ, C_{d}) corresponding to the first pattern is output.

The chuck temperature control parameter setting unit 104 sets the heating control parameter and the cooling control parameter to which the adjustment coefficient (Cₚ, Cᵢ, C_{d}) is applied, for the chuck temperature adjusting unit. A step of setting the heating control parameter and the cooling control parameter for the chuck temperature adjusting unit may be included in the chuck temperature control method as a chuck temperature control parameter setting step.

After the chuck temperature acquiring step S10 shown in FIG. 14, a step of deriving the change in the chuck temperature from chuck temperatures sequentially acquired in chronological, may be executed. Alternatively, the step of deriving the change in the chuck temperature may be executed integrally with the chuck temperature acquiring step S10.

After the step of deriving the change in the chuck temperature, a step of deriving a feature amount corresponding to the change in chuck temperature from the change in the chuck temperature, may be executed. The step of deriving the feature amount may be executed integrally with the step of deriving the change in the chuck temperature.

Before the classifying step S12, a learned model selecting step of determining the type of the wafer W to be measured and selecting the learned model 200 in accordance with the type of the wafer W may be executed. The learned model selecting step may be executed integrally with the classifying step S12.

### Specific Example of Chuck Temperature Control

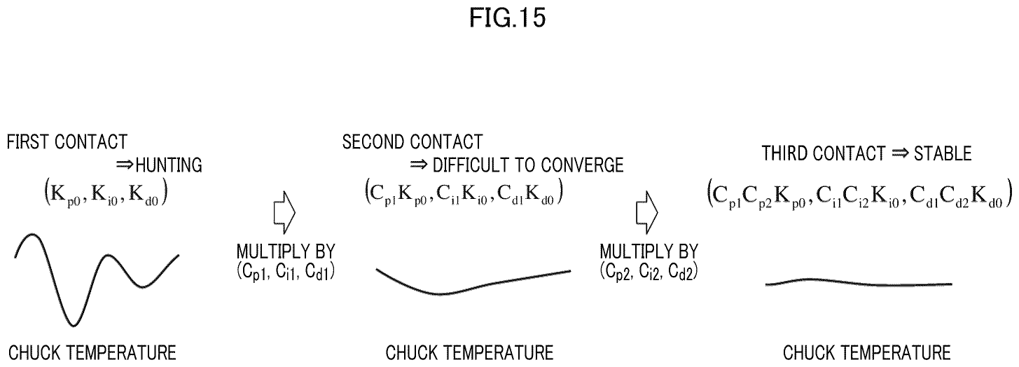

FIG. 15 is a schematic diagram illustrating a specific example of chuck temperature control. FIG. 15 shows a case where semiconductor chips 9 included in one wafer W is sequentially inspected in a similar manner to FIG. 7.

An initial value (Kₚ₀, Kᵢ₀, K_{d0}) of the chuck temperature control parameter is set when performing the inspection of the first semiconductor chip 9 indicated as the first contact. In the first contact, for example, in a case where the change in the chuck temperature is classified into the first pattern in which hunting of the change in the chuck temperature occurs, the adjustment coefficient (Cₚ₁, Cᵢ₁, C_{d1}) corresponding to the first pattern is acquired.

A chuck temperature control parameter (Cₚ₁×Kₚ₀, Cᵢ₁×Kᵢ₀, C_{d1}×K_{d0}) is set in the second contact. In the second contact, for example, in a case where the change in the chuck temperature is classified into the second pattern in which the convergence period is long, the adjustment coefficient (Cₚ₂, Cᵢ₂, C_{d2}) corresponding to the second pattern is acquired.

A chuck temperature control parameter (Cₚ₁×Cₚ₂×Kₚ₀, Cᵢ₁×Cᵢ₂×Kᵢ₀, C_{d1}×C_{d2}×K_{d0}) is applied in the third contact. FIG. 15 shows a case where, for example, the change in the chuck temperature in the third contact is classified into the fourth pattern in which the chuck temperature is stable.

In the fourth and subsequent contacts, an adjustment coefficient (1, 1, 1) corresponding to the fourth pattern in which the chuck temperature is stable is applied to a chuck temperature control parameter (Cₚ₁×Cₚ₂×Kₚ₀, Cᵢ₁×Cᵢ₂×Kᵢ₀, C_{d1}×C_{d2}×K_{d0}). The adjustment coefficient (1, 1, 1) is applied in a case where the chuck temperature control parameter applied in the previous contact is not changed.

In other words, when the adjustment coefficient (Cₚ₁×Cₚ₂, Cᵢ₁×Cᵢ₂, C_{d1}×C_{d2}) is conclusively applied to the chuck temperature control parameter (Kₚ₀, Kᵢ₀, K_{d0}) corresponding to the change in the chuck temperature acquired upon the first contact, chuck temperature is controlled so as to achieve a stable chuck temperature.

Thus, in a case where relearning of the learned model 200 is performed using the change in the chuck temperature acquired in the first contact and the adjustment coefficient of the chuck temperature control parameter with which a stable chuck temperature is achieved, chuck temperature may be controlled with further high accuracy. Even in a case where a combination of the PID control loops is changed and in a case where the number of the PID control loops increases, the automatic adjustment of the chuck temperature control parameter using machine learning may be performed by increasing explanatory variables,.

The first contact shown in FIG. 15 is grasped as an n-th contact in a case where n is an integer. The second contact shown in FIG. 15 is grasped as a j-th contact in a case where j is an integer exceeding n. The third contact shown in FIG. 15 is grasped as a k-th contact in a case where k is an integer exceeding j. The adjustment coefficient (Cₚ, Cᵢ, C_{d}) may be applied to an initial value (Kₚ₀, Kᵢ₀, K_{d0}) of the chuck temperature control parameter in the n-th contact.

### Modification of Chuck Temperature Control

In the inspection of the wafer W shown in FIG. 7, a semiconductor chip 94 is inspected after the inspection of a semiconductor chip 93, and in a case where the change in the chuck temperature shown in the graph G14 is acquired during the inspection of the semiconductor chip 94, the chuck temperature control unit 21 illustrated in FIG. 5 may be configured so as not to update the chuck temperature control parameter.

In other words, the chuck temperature control unit 21 may be configured so as to determine whether or not the chuck temperature acquired during the inspection of the wafer W deviates from the specified allowable temperature range, and update the chuck temperature control parameter in a case where the chuck temperature deviates from the specified allowable temperature range. Further, in a case where the chuck temperature falls within the specified allowable temperature range, the chuck temperature control unit 21 may be configured so as not to update the chuck temperature control parameter.

### Configuration Example of Program to be Executed by Computer

Various kinds of functions of the chuck temperature control unit 21 illustrated in FIG. 5 may be implemented by a computer executing programs. Examples of the various kinds of functions to be implemented by the computer may include a function of acquiring the chuck temperature, a function of classifying the change in the chuck temperature into specified patterns, and a function of acquiring the chuck temperature control parameter based on the pattern of the change in the chuck temperature. The programs are recorded in a non-transitory computer-readable storage medium.

### Operational Effects of Embodiment

The chuck temperature control to be applied to the prober according to the embodiment may achieve the following operational effects.
[1]

A feature of the temperature change of the wafer chuck 20 is classified into one of temperature change patterns specified in advance, using the learned model 200 obtained by learning features of the temperature changes of the wafer chuck 20 and the temperature change patterns of the wafer chuck 20. The temperature control parameter corresponding to each classified temperature change pattern is derived. The chuck temperature adjusting unit 20a that adjusts the chuck temperature using the derived temperature control parameter. By this means, it is possible to implement automatic temperature adjustment of the wafer chuck 20 according to the temperature change of the wafer chuck 20.
[2]

A feature amount representing the feature of the temperature change of the wafer chuck 20 is used as the feature of the temperature change of the wafer chuck 20. The learning model learns (is trained) a correspondence relationship between a feature amount representing a feature of the temperature change in the chuck temperature and a specified temperature change pattern. The learned model outputs the temperature change pattern corresponding to the feature amount in response to input of the feature amount representing the feature of the temperature change in the chuck temperature. By this means, an infinite number of temperature changes of the chuck temperature are classified into the temperature change patterns specified in advance.
[3]

The learned model corresponding to the wafer to be inspected is selected from the learned models respectively corresponding to wafers of different types. By this means, the change in the chuck temperature is classified according to the type of the wafer to be inspected.
[4]

PID control parameters are used as the chuck temperature control parameters. The PID control parameters (Cₚ×Kₚ, Cᵢ×Kᵢ, C_{d}×K_{d}) obtained by multiplying the previously set PID control parameters (Kₚ, Kᵢ, K_{d}) by the adjustment coefficients (Cₚ, Cᵢ, C_{d}) are used as the chuck temperature control parameters. By this means, it is possible to implement chuck temperature control using a new PID control parameters based on the previously set PID control parameters.
[5]

As the chuck temperature control parameter, the adjustment coefficient (Cₚ, Cᵢ, C_{d}) by which the PID control parameter (Kₚ, Kᵢ, K_{d}) is to be multiplied is derived. By this means, the chuck temperature control parameter appropriate for PID control is derived.

Components in the above-described embodiment of the present invention may be changed, added or deleted as appropriate within a range not departing from the gist of the present invention. The present invention is not limited to the embodiment described above, and many modifications may be made by a person having ordinary knowledge in this field within technical idea of the present invention. Further, the embodiment, modifications and application examples may be combined as appropriate in implementation of the present invention.

### REFERENCE SIGNS LIST

9 semiconductor chip
9a electrode pad
10 prober
12 base
13 Y stage
14 Y moving part
15 X stage
16 X moving part
17 Zθ stage
18 Zθ moving part
20 wafer chuck
20a chuck temperature adjusting unit
20b chuck temperature sensor
21 chuck temperature control unit
21a chuck temperature control unit
23 pillar
24 head stage
25 card holder
25a holding hole
26 probe card
29 wafer positioning camera
30 vertical stage
31 needle positioning camera
32 cleaning plate
34 temperature sensor
35 probe needle
40 control device
42 card temperature acquiring unit
44 needle position acquiring unit
46 wafer information acquiring unit
52 movement control unit
91 semiconductor chip
92 semiconductor chip
93 semiconductor chip
94 semiconductor chip
100 chuck temperature acquiring unit
102 classifying unit
102a classifying unit
103 learned model acquiring unit
104 chuck temperature control parameter setting unit
104a chuck temperature control parameter setting unit
110 heating control parameter deriving unit
110a heating control parameter deriving unit
112 cooling control parameter deriving unit
112a cooling control parameter deriving unit
200 learned model
210 output
G1 graph
G2 graph
G3 graph
G10 graph
G12 graph
G14 graph
G20 graph
G22 graph
G24 graph
G26 graph
G30 graph
G32 graph
G34 graph
G40 graph
G42 graph
G44 graph
G46 graph
G50 graph
SP1 temperature change sample
SP2 temperature change sample
SP3 temperature change sample
SP4 temperature change sample
SP5 temperature change sample
SP6 temperature change sample
W wafer

What is claimed is:

1. A temperature control device comprising:
a chuck temperature acquiring unit configured to acquire chuck temperature indicating a temperature of a wafer chuck that holds a wafer having semiconductor chips formed thereon;
a classifying unit configured to receive the chuck temperature and output a temperature change pattern corresponding to change in the received chuck temperature, using a learned model generated through learning with a correspondence relationship between features of changes in the chuck temperature and a predetermined number of temperature change patterns representing classification of the changes in the chuck temperature; and
a temperature control parameter setting unit configured to derive a temperature control parameter corresponding to the temperature change pattern output from the classifying unit in a case where the classifying unit receives the chuck temperature, and set the temperature control parameter,
wherein operation of a chuck temperature adjusting unit configured to adjust the chuck temperature is controlled using the temperature control parameter set by the temperature control parameter setting unit.

2. The temperature control device according to claim 1, comprising
a chuck temperature change deriving unit configured to derive a change in the chuck temperature from the chuck temperatures acquired at different timings.

3. The temperature control device according to claim 1, wherein
the learned model learns a correspondence relationship between feature amounts representing the features of the changes in the chuck temperature and the temperature change patterns representing the classification of the changes of the chuck temperature, and
the classifying unit acquires a feature amount as a feature of the change in the chuck temperature and outputs the temperature change pattern corresponding to the feature amount.

4. The temperature control device according to claim 1, wherein the temperature control parameter setting unit derives the temperature control parameter in which an adjustment coefficient corresponding to the temperature change pattern is used.

5. The temperature control device according to claim 1, comprising:
a wafer information acquiring unit configured to acquire wafer information including a type of a wafer to be measured; and
learned models generated by performing the learning for each type of the wafer,
wherein the classifying unit selects one of the learned models corresponding to the type of the wafer included in the wafer information acquired by the wafer information acquiring unit.

6. A temperature control method to be executed by a computer, the temperature control method comprising:
a step of acquiring a chuck temperature indicating a temperature of a wafer chuck that holds a wafer having semiconductor chips formed thereon;
a step of, in a case where the chuck temperature is input, outputting a temperature change pattern corresponding to a change in the input chuck temperature, with a classifying unit which uses a learned model generated through learning with a correspondence relationship between features of changes in the chuck temperature and a predetermined number of temperature change patterns representing classification of the changes in the chuck temperature,
a step of deriving a temperature control parameter corresponding to the temperature change pattern output from the classifying unit in a case where the chuck temperature is input to the classifying unit, and setting the temperature control parameter; and
a step of controlling operation of a chuck temperature adjusting unit that adjusts the chuck temperature using the temperature control parameter.

7. A non-transitory, computer-readable tangible recording medium which records thereon, a program for causing a computer to implement:
a function of acquiring a chuck temperature indicating a temperature of a wafer chuck that holds a wafer having semiconductor chips formed thereon;
a function of, in a case where the chuck temperature is input, outputting a temperature change pattern corresponding to a change in the input chuck temperature, with a classifying unit which uses a learned model generated through learning with a correspondence relationship between features of changes in the chuck temperature and a predetermined number of temperature change patterns representing classification of the changes in the chuck temperature;
a function of deriving a temperature control parameter corresponding to the temperature change pattern output from the classifying unit in a case where the chuck temperature is input to the classifying unit, and setting the temperature control parameter; and
a function of controlling operation of a chuck temperature adjusting unit that adjusts the chuck temperature using the temperature control parameter.

8. A prober comprising:
a wafer chuck configured to hold a wafer having semiconductor chips formed thereon;
a probe card having probe needles;
a relative moving unit configured to move the wafer chuck relatively to the probe needles;
a chuck temperature adjusting device configured to adjust a temperature of the wafer chuck; and
a temperature control device configured to control operation of the chuck temperature adjusting device using a temperature control parameter,
wherein the temperature control device includes:
a chuck temperature acquiring unit configured to acquire chuck temperature indicating a temperature of a wafer chuck that holds a wafer having semiconductor chips formed thereon;
a classifying unit configured to receive the chuck temperature and output a temperature change pattern corresponding to change in the received chuck temperature, using a learned model generated through learning with a correspondence relationship between features of changes in the chuck temperature and a predetermined number of temperature change patterns representing classification of the changes in the chuck temperature; and
a temperature control parameter setting unit configured to derive a temperature control parameter corresponding to the temperature change pattern output from the classifying unit in a case where the classifying unit receives the chuck temperature, and set the temperature control parameter, and
operation of the chuck temperature adjusting unit that adjusts the chuck temperature is controlled using the temperature control parameter set by the temperature control parameter setting unit.

9. A learning model generating method for generating a learned model which have learned a correspondence relationship between features of changes in a chuck temperature indicating a temperature of a wafer chuck that holds a wafer having semiconductor chips formed thereon, and a predetermined number of temperature change patterns representing classification of the changes in the chuck temperature.
